(19) United States
(12) Patent Application Publication
(10) Pub. No.: US 2026/0358183 A1
(43) Pub. Date: Nov. 12, 2026

(54) PRESSURE GAUGE POWER SUPPLY UNIT

(71) Applicant: Edwards Limited, Burgess Hill, Sussex (GB)

(72) Inventors: Gary Michael George Lord, Eastbourne, Sussex (GB); Jonathan Reeve-Fowkes, Eastbourne, Sussex (GB); Jayne Marie Schjerve, Eastbourne, Sussex (GB); Glen Croft, Eastbourne, Sussex (GB); Ylber Doniku, Eastbourne, Sussex (GB); Bishoy Zakaria, Eastbourne, Sussex (GB); Nicholas Daniel Hutton, Eastbourne, Sussex (GB); Janos Gabor Kristof, Eastbourne, Sussex (GB)

(21) Appl. No.: 19/103,082

(22) PCT Filed: Aug. 11, 2023
(86) PCT No.: PCT/GB2023/052123

§ 371 Date: Feb. 11, 2025

(30) Foreign Application Priority Data
Aug. 12, 2022 (GB) 2211804.6

(51) Int. Cl. G01L 21/30; H05K 1/14; H05K 3/28

(52) U.S. Cl. CPC G01L 21/30; H05K 1/144; H05K 3/284; H05K 2201/10189

(57) ABSTRACT

Aspects of the present invention relate to a power supply unit configured to be integrated into a vacuum pressure gauge. The vacuum pressure gauge having a vacuum pressure sensor. The power supply unit includes a motherboard and a daughterboard. The motherboard has a first surface and a second surface. A transformer having a primary coil and a secondary coil is mounted to the motherboard. The daughterboard has one or more first electrical connectors for supplying power to the vacuum pressure sensor. At least a portion of the first surface of the motherboard and at least a portion of the daughterboard are encapsulated in an electrical potting compound. Aspects of the present invention relate to vacuum pressure gauge including a power supply unit; a mounting arrangement of a power supply to a vacuum pressure sensor; and a method of manufacturing a power supply unit.

### CROSS-REFERENCE OF RELATED APPLICATION

This application is a Section 371 National Stage Application of International Application No. PCT/GB2023/052123, filed Aug. 11, 2023, and published as WO 2024/033655 A1 on Feb. 15, 2024, the content of which is hereby incorporated by reference in its entirety and which claims priority of British Application No. 2211804.6, filed Aug. 12, 2022.

### FIELD

The present disclosure relates to a pressure gauge power supply unit. Aspects of the invention relate to a power supply unit, a pressure gauge and a method of manufacturing a pressure gauge. The pressure gauge is typically a vacuum pressure gauge for measuring a vacuum pressure.

### BACKGROUND

Pressure gauges are commonly used to measure the pressure in industrial systems. The pressure measurement can be used to check that the system has an appropriate pressure for its intended purpose. For example, a vacuum pressure gauge may be used in a vacuum system. If the measurement indicates that the pressure in the system is insufficiently low this can be used to indicate and detect a leak or defect in the system and/or provide feedback to aid control of a vacuum pump evacuating the system.

This description generally exemplifies a pressure sensor for a vacuum pressure gauge assembly as ‘a pressure transducer’, which is generally known to generate a signal (e.g., an electrical signal) as a function of the pressure imposed thereon. As will be appreciated by the skilled person, a broad range of suitable pressure transducers and vacuum pressure gauge assemblies are known, and it is to be understood that any such suitable type or combination of pressure transducer(s) and gauge assembly(ies) may benefit from this disclosure and are accordingly within the scope thereof.

Such types of gauge assemblies may include, for example, Pirani gauge assemblies, thermocouple gauge assemblies, ionization gauge assemblies (e.g. hot-cathode gauge assemblies or cold-cathode gauge assemblies (such as Penning gauge assemblies), magnetron gauge assemblies, inverted magnetron gauge assemblies, wide range gauge assemblies, strain gauge assemblies, etc.

As the working principles of such vacuum pressure gauge assemblies and the pressure transducers (i.e., pressure sensing elements) therein are readily known to the skilled person, they will not be described in further detail here.

It is an aim of the present invention to provide improvements over known vacuum pressure gauges.

The discussion above is merely provided for general background information and is not intended to be used as an aid in determining the scope of the claimed subject matter. The claimed subject matter is not limited to implementations that solve any or all disadvantages noted in the background.

### SUMMARY

Aspects and embodiments of the invention provide a power supply unit configured to be integrated into a vacuum pressure gauge comprising a vacuum pressure sensor, the power supply unit comprising:
a motherboard comprising a first surface and a second surface, wherein a transformer having a primary coil and a secondary coil is mounted to the motherboard; and
a daughterboard comprising one or more first electrical connectors for supplying power to the vacuum pressure sensor;
wherein at least a portion of the first surface of the motherboard and at least a portion of the daughterboard are encapsulated in an electrical potting compound. At least in certain embodiments, the electrical potting compound forms a permanent protective layer which forms an integral part of the power supply unit. The electrical potting compound protects the electronic assembly and may provide electrical insulation and/or improved mechanical strength. The power supply unit may be integrated into the vacuum pressure gauge to form a self-contained device. For example, the power supply unit and the vacuum pressure gauge may be disposed in a housing.

The vacuum pressure gauge may comprise an ionization vacuum pressure sensor having a cathode and an anode. The ionization vacuum pressure sensor may comprise a hot cathode or a cold cathode ionization vacuum pressure. In use, the transformer may output a high voltage to the ionization vacuum pressure sensor.

The transformer may comprise an auxiliary winding. The transformer may be mounted to the second surface of the motherboard. The transformer may be surface mounted to the second surface of the motherboard.

The daughterboard may be mounted to the first surface of the motherboard. The daughterboard may be surface mounted to the first surface of the motherboard. The daughterboard may be mounted using a surface mount assembly process. This may facilitate assembly of the power supply unit. For example, the daughterboard may be surface mounted to the motherboard concurrently with other electrical components. The one or more first electrical connectors provided on the daughterboard may be spaced apart from the first surface of the motherboard.

The daughterboard may comprise a first surface and a second surface. The second surface of the daughterboard may be disposed adjacent to the first surface of the motherboard. The one or more first electrical connectors may be disposed on the first surface of the daughterboard.

The one or more first electrical connectors may be surface mounted to the daughterboard. Alternatively, the one or more first electrical connectors may be through-hole mounted to the daughterboard. This may provide enhanced structural integrity for the one or more first electrical connectors.

The first electrical connectors are preferably at least substantially unimpeded by the electrical potting compound. The electrical potting compound is preferably not provided over the first electrical connectors.

The electrical potting compound may be provided at least partway around an outer circumference of the daughterboard. The electrical potting compound may be at least substantially level with the first (upper) surface of the daughterboard. The electrical potting compound may at least partially encapsulate the first (upper) surface of the daughterboard.

At least in certain embodiments, the transformer has a first major surface and a second major surface. The first major surface may be oriented in the same direction as the first surface of the motherboard. The second major surface may be oriented in the same direction as the second surface of the motherboard. The first major surface of the transformer may be at least partially encapsulated in the electrical potting compound.

The second surface of the motherboard may be at least substantially free of the electrical potting compound. At least in certain embodiments, the second surface of the motherboard is not encapsulated in the electrical potting compound.

The electrical potting compound may extend to an outer perimeter of the power supply unit. A sidewall of the electrical potting compound may form an outer edge or a perimeter of the power supply unit.

The power supply unit may comprise one or more voltage multipliers. The one or more voltage multipliers may be provided on the motherboard.

According to a further aspect of the present invention there is provided a vacuum pressure gauge comprising a power supply unit as described herein. The power supply unit may be integrated into the vacuum pressure gauge.

The vacuum pressure gauge may comprise a vacuum pressure sensor. The vacuum pressure sensor may comprise or consist of an ionization vacuum pressure sensor. The vacuum pressure sensor may comprise or consist of a hot cathode or a cold cathode ionization vacuum pressure sensor.

According to a further aspect of the present invention there is provided a method of assembling a power supply unit configured to be integrated into a vacuum pressure gauge, the power supply unit comprising a motherboard comprising a first surface and a second surface; and a daughterboard comprising one or more first electrical connectors; the method comprising:
mounting the daughterboard to the first surface of the motherboard to form a sub-assembly;
locating the sub-assembly in a mould cavity and at least substantially sealing the mould cavity;
introducing an electrical potting compound into the mould cavity at least partially to encapsulate the daughterboard and the first surface of the motherboard; and
curing the electrical potting compound and then removing the power supply unit from the mould cavity.

A transformer may be mounted to the motherboard. The transformer may comprise a primary coil and a secondary coil. The transformer may comprise an auxiliary coil. One or more voltage multipliers may be provided on the motherboard.

The one or more first electrical connectors provided on the daughterboard may be configured to supply power to a vacuum pressure sensor.

A seal may be formed around a periphery of the motherboard when the sub-assembly is located in the mould cavity.

The seal may be formed between the motherboard and an internal wall of the mould cavity. The seal may be formed between an edge of the motherboard and the internal wall of the mould cavity. Alternatively, or in addition, the seal may be formed between a surface of the motherboard and the internal wall of the mould cavity.

At least in certain embodiments, the seal may at least substantially prevent the electrical potting compound from encapsulating the second side of the motherboard.

At least in certain embodiments, the method may comprise forming a seal around the at least one first electrical connector provided on the daughterboard. This may prevent the electrical potting compound encapsulating the at least one first electrical connector. The or each first electrical connector may be at least partially located in a mould recess formed in the mould cavity. The seal may be formed between an internal wall of the mould recess and an outer wall of the first electrical connector.

The or each first electrical connector may comprise an electrical socket. One or more projections may be formed in the mould cavity. The one or more projections may locate in a respective one of the electrical sockets. The one or more projections may at least substantially seal the respective electrical socket.

The electrical potting compound may be introduced into the mould cavity under vacuum. A vacuum may be formed in the mould cavity prior to introducing the electrical potting compound.

Any control unit or controller described herein may suitably comprise a computational device having one or more electronic processors. The system may comprise a single control unit or electronic controller or alternatively different functions of the controller may be embodied in, or hosted in, different control units or controllers. As used herein the term “controller” or “control unit” will be understood to include both a single control unit or controller and a plurality of control units or controllers collectively operating to provide any stated control functionality. To configure a controller or control unit, a suitable set of instructions may be provided which, when executed, cause said control unit or computational device to implement the control techniques specified herein. The set of instructions may suitably be embedded in said one or more electronic processors. Alternatively, the set of instructions may be provided as software saved on one or more memory associated with said controller to be executed on said computational device. The control unit or controller may be implemented in software run on one or more processors. One or more other control unit or controller may be implemented in software run on one or more processors, optionally the same one or more processors as the first controller. Other suitable arrangements may also be used.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

The Summary is provided to introduce a selection of concepts in a simplified form that are further described in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

One or more embodiments of the invention will now be described, by way of example only, with reference to the accompanying drawings, in which:

FIG. 1 shows a perspective view of a vacuum pressure gauge in accordance with an embodiment of the present invention;

FIG. 2 shows a circuit diagram for a power supply unit in the vacuum pressure gauge shown in FIG. 1;

FIG. 3 shows a perspective view of a first side of the power supply unit without an electrical potting compound;

FIG. 4 shows a perspective view of a first side of the power supply unit with an electrical potting compound;

FIG. 5 shows a perspective view of a second side of the power supply unit;

FIG. 6 shows a perspective view of a first side of a daughterboard for mounting first electrical connectors in the power supply unit;

FIG. 7 shows a perspective view of a second side of the daughterboard shown in FIG. 6;

FIG. 8 shows a perspective view of the electrical connectors provided on a vacuum pressure sensor for use in the vacuum pressure gauge in accordance with an embodiment of the present invention;

FIG. 9 shows a schematic representation of a controller for ta control unit in the vacuum pressure gauge;

FIG. 10 shows a first perspective view of the control unit and the power supply in a chassis for mounting to the vacuum pressure sensor;

FIG. 11 shows a second perspective view of the control unit and the power supply in a chassis for mounting to the vacuum pressure sensor;

FIG. 12 shows a perspective view of a mould tool for forming an electric potting compound on the power supply unit; and

FIG. 13 shows a perspective view of a jig for supporting a plurality of the mould tools shown in FIG. 12.

### DETAILED DESCRIPTION

A vacuum pressure gauge 1 in accordance with an embodiment of the present invention will now be described with reference to the accompanying figures. The vacuum pressure gauge 1 is used for measuring the vacuum pressure of a vacuum system component (denoted generally by the reference VSC). The vacuum system component VSC may, for example, be in the form of a vacuum pump.

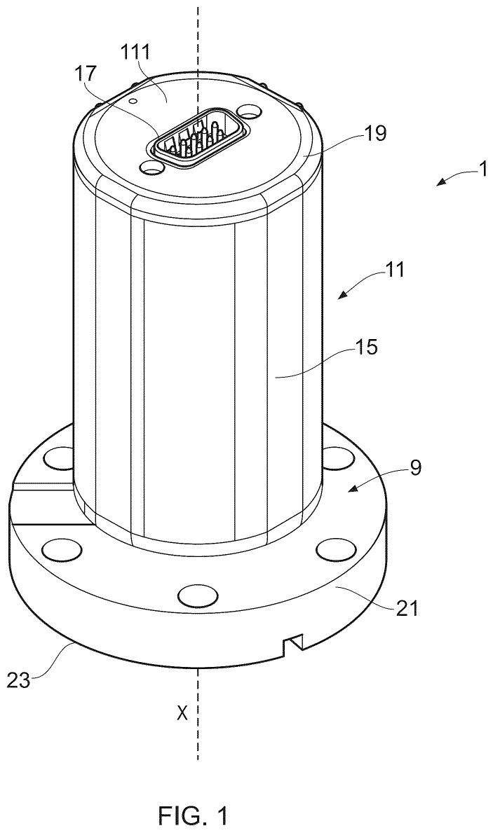

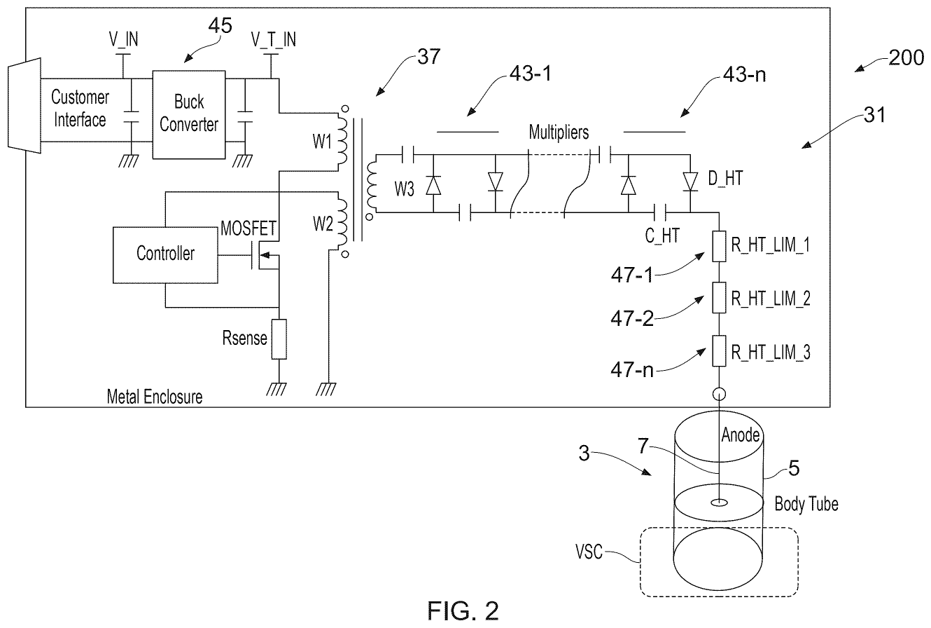

A perspective view of the assembled vacuum pressure gauge 1 is shown in FIG. 1. The vacuum pressure gauge 1 comprises an ionization vacuum pressure sensor 3. In the present embodiment, the ionization vacuum pressure sensor 3 is a cold cathode ionization vacuum pressure sensor. The ionization vacuum pressure sensor 3 comprises a cathode 5 and an anode 7 (shown schematically in FIG. 2). In use, a high voltage is applied to the anode 7 and negatively charged electrons leave the cathode 5 through field emission and travel toward the anode 7. The electrons ionize neutral gas molecules resulting in a gas discharge current which is measured to determine the vacuum pressure. The ionization vacuum pressure sensor 3 also comprises a Pirani filament (not shown) and a striker filament (not shown). In a variant, the ionization vacuum pressure sensor 3 may be a hot cathode ionization vacuum pressure sensor. Other types of vacuum gauge sensor may be used in the vacuum pressure gauge 1.

The vacuum pressure gauge 1 comprises a base 9, a body 11 and an (upper) end member 13. The vacuum pressure gauge 1 comprises a central longitudinal axis X. The body 11 is elongated along the central longitudinal axis X. In the present embodiment, the body 11 is generally cylindrical in shape and has a circular profile in transverse section. The body 11 comprises a housing 15 provided around the ionization vacuum pressure sensor 3. The housing 15 comprises a tubular sleeve in the form of a right cylinder. As described herein, the housing 15 is removable from the vacuum pressure gauge 1. An upper end of the housing 15 is closed by the end member 13. At least one external interface connector 17 is provided in the end member 13 for connection to an external computational device (not shown). The vacuum pressure gauge 1 in the present embodiment also comprises a status indicator 19. The status indicator 19 is in the form of an annulus extending around the circumference of the end member 13. In use, at least a portion of the status indicator 19 can be controllably illuminated to indicate the operating status of the vacuum pressure gauge 1 and/or an operating pressure measured by the ionization vacuum pressure sensor 3. The status indicator 19 may comprise one or more light emitting devices (not shown), such as light emitting diodes (LEDs). It will be understood that the body 11 of the vacuum pressure gauge 1 may have different shapes and/or profiles. For example, the body 3 may have a cross-section in the form of a polygon or a rounded polygon.

The body 11 could be made of any suitable material, such as a stainless steel or aluminium alloy, or polymeric material (where operating conditions and temperature permit). The body 11 can also be made from any suitable manufacturing method, such as by being moulded/cast, machined from a solid block or 3D printed.

The base 9 is configured to be fastened to the vacuum system component VSC, for example using one or more mechanical fasteners. A flange 21 extends from the base 9 in a radial direction. In one example, the flange 21 is of the NW25 specification, although any suitable size and shape of flange may be used within the scope of this disclosure. The flange 21 includes a mating face 23 for interfacing with the vacuum system component VSC from which the pressure is to be measured. The mating face 23 may optionally comprise an annular recess (not illustrated) for receiving an O-ring to provide a seal between the vacuum pressure gauge 1 and the vacuum system component VSC.

The flange 21 comprises an inlet passage (not shown) for a chamber formed in the ionization vacuum pressure sensor 3. The inlet passage extends axially from the mating face, through the flange 21 and into the chamber. The inlet passage is in fluid communication with the chamber and, in use, permits the ingress and egress of the working gas (e.g., from the vacuum system component VSC). A filter element (not shown) may be provided across the inlet passage for filtering the working gas before it enters the chamber. The filter element helps to prevent contaminants from entering the chamber. The filter element may, for example, comprise a stainless steel (e.g., 316L) 30-2 mesh, although any other suitable type (e.g. a membrane), material and specification of filter element may be used within the scope of this disclosure.

By ‘working or process gas’, it is meant the gas (or gases) that the assembly intends to measure the pressure of. The ‘working gas’ is usually the gas (or gases) that are being worked on (e.g. being evacuated by the vacuum system component VSC). The pressure of the gas in the chamber can provide an indication of the pressure in the vacuum system.

The vacuum pressure gauge 1 comprises a power supply unit 31 and a control unit 35. The power supply unit 31 is configured to supply power to the ionization vacuum pressure sensor 3. In use, the power supply unit 31 outputs a high voltage to the anode 7 of the ionization vacuum pressure sensor 3. The power supply unit 31 is integrated into the vacuum pressure gauge 1. A circuit diagram 200 for the power supply unit 31 is shown in FIG. 2. The circuit diagram 200 includes a schematic representation of the ionization vacuum pressure sensor 3. The power supply unit 31 comprises a transformer 37 having a primary coil W1, an auxiliary coil W2 and a secondary coil W3. In the present embodiment, the transformer 37 is a planar transformer, but other types of transformer may be used. The transformer 37 comprises first and second opposing major surfaces 39A, 39B. The secondary coil W3 is connected to the anode 7 of the ionization vacuum pressure sensor 3. The power supply unit 31 comprises a plurality of first electrical connectors 41-n for connection to the ionization gauge sensor 3. In the present embodiment, the first electrical connectors 41-n each comprise an electrical socket.

As shown in FIG. 2, the power supply unit 31 comprises one or more voltage multipliers 43-n. A plurality of the voltage multipliers 43-n is provided in the present embodiment. The voltage multipliers 43-n are provided to multiply the voltage output from the secondary coil W3 of the transformer 37. The voltage multipliers 43-n may, for example, enable the generation of a voltage up to 5 kV. The transformer 37 and the voltage multipliers 43-n are arranged in a fly-back topology with an operating frequency in the range of 10 to 100 KHz. Advantageously, the voltage multipliers 43-n may enable relatively low response times for the vacuum pressure gauge 1. The output capacitance of the transformer 37 may be reduced. The voltage multipliers 43-n may be provided in a small area, thereby enabling a compact footprint for the power supply unit 31. The power supply unit 31 optionally comprises a primary step-down power supply 45 to reduce or remove the effect of input supply variability on the high voltage output from the transformer 37. The high voltage output may remain at least substantially unchanged regardless of the input supply. The primary step-down power supply 45 is a buck converter (step-down converter) in the present embodiment.

The power supply unit 31 comprises one or more high voltage resistors 47-n connected between the voltage multipliers 43-n and the high voltage output. The resistors 47-n limit the current and output power from the power supply unit 31. The voltage applied to the ionization vacuum pressure sensor 3 may vary during ignition depending on the operating conditions. For example, ignition may occur more readily at higher pressures than at lower pressures. The resistors 47-n may limit the voltage applied to the ionization vacuum pressure sensor 3, for example during ignition. The resistors 47-n allow for a larger voltage at lower vacuum pressures to aid ignition of the ionization vacuum pressure sensor 3. The resistors 47-n may also provide secondary protection against user misuse.

The mounting arrangement of the transformer 37 and the first electrical connectors 41-n in the power supply unit 31 will now be described in more detail. The power supply unit 31 comprises a first printed circuit board (PCB) 55 having a first (lower) surface 57A and a second (upper) surface 57B; and a second printed circuit board (PCB) 65 having a first (lower) surface 67A and a second (upper) surface 67B. The first printed circuit board 55 has a substantially circular profile for location inside the body 11 of the vacuum pressure gauge. The first printed circuit board 55 may have different profiles. The second printed circuit board 65 is mounted to the first surface 57A of the first printed circuit board 55 in a face-to-face arrangement. The second printed circuit board 65 has a thickness of approximately 4.5 mm. The thickness of the second printed circuit board 65 may be larger than or smaller than 4.5 mm. In the present embodiment, the second printed circuit board 65 is surface mounted to the first printed circuit board 55. Other techniques may be used to mount the second printed circuit board 65 to the first printed circuit board 55. The first and second printed circuit boards 55, 65 comprise respective first and second electrical traces to establish electrical connections. The first printed circuit board 55 is referred to herein as a motherboard 55; and the second printed circuit board 65 is referred to herein as a daughterboard 65.

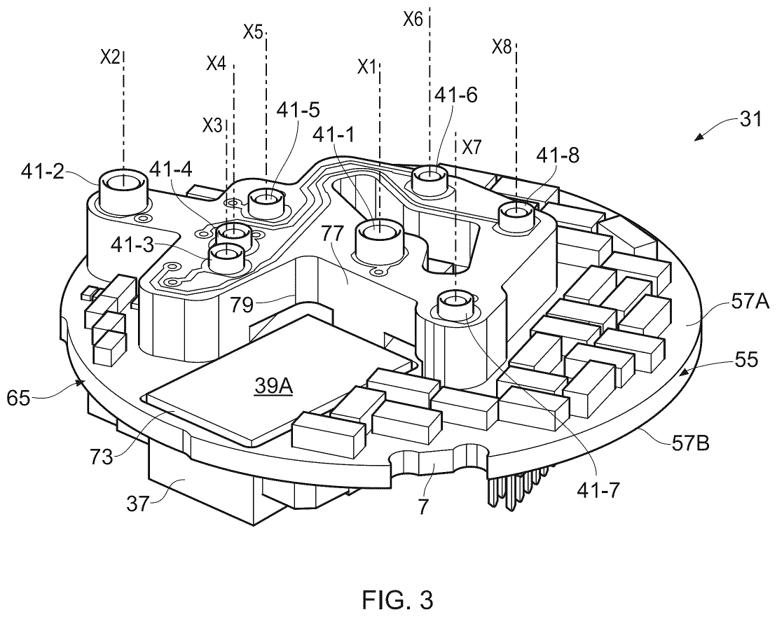

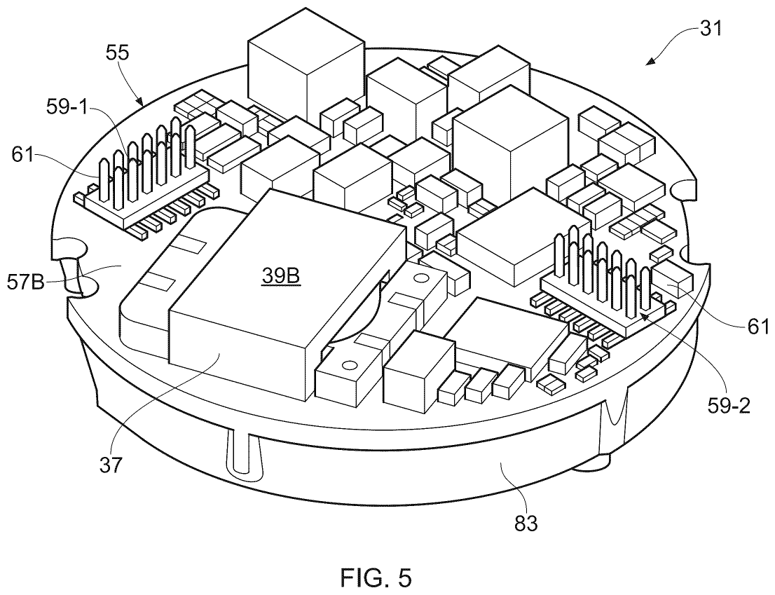

As shown in FIGS. 3 and 5, the motherboard 55 comprises a through-aperture 73 for receiving the transformer 37. The transformer 37 is mounted to the second surface 57B of the motherboard 55 and is at least partially located in the through-aperture 73. This mounting arrangement reduces the vertical packaging requirements for the transformer 37 in the body 11 of the vacuum pressure gauge 1. The first major surface 39A may be aligned with or offset from the first surface 57A of the motherboard 55. In the present embodiment, the transformer 37 is mounted such that the first major surface 39A projects outwardly from the first surface 57A of the motherboard 55. The voltage multipliers 43-n and the high voltage resistors 47-n are mounted to the first surface 57A of the motherboard 55. The power supply unit 31 comprises at least one control interface connector 59-n for communicating with the control unit 35. is mounted to the second surface 57B of the motherboard 55. In the present embodiment, the power supply unit 31 comprises first and second control interface connectors 59-1, 59-2. The first and second control interface connectors 59-1, 59-2 each comprise a plurality of input/output pins 61, for example General Purpose Input Output (GPIO) pins. The input/output pins 61 may be, for example, be provided in a header unit. The input/output pins 61 project substantially perpendicular to the second surface 57B. The input/output pins 61 are configured to locate in complementary connectors (not shown) provided on the control unit 35. The control unit 35 is mounted on the power supply unit 31 in a Hardware Attached on Top (HAT) configuration. At least one of the first and second control interface connectors 59-1, 59-2 is configured to output control signals from the control unit 35 to the power supply unit 31. The first and second control interface connectors 59-1, 59-2 may also be used to supply power to the power supply unit 31.

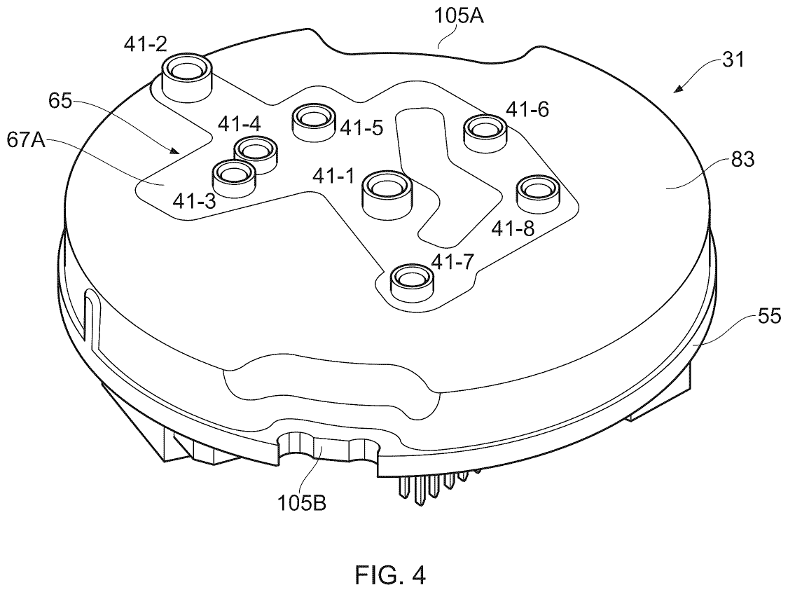

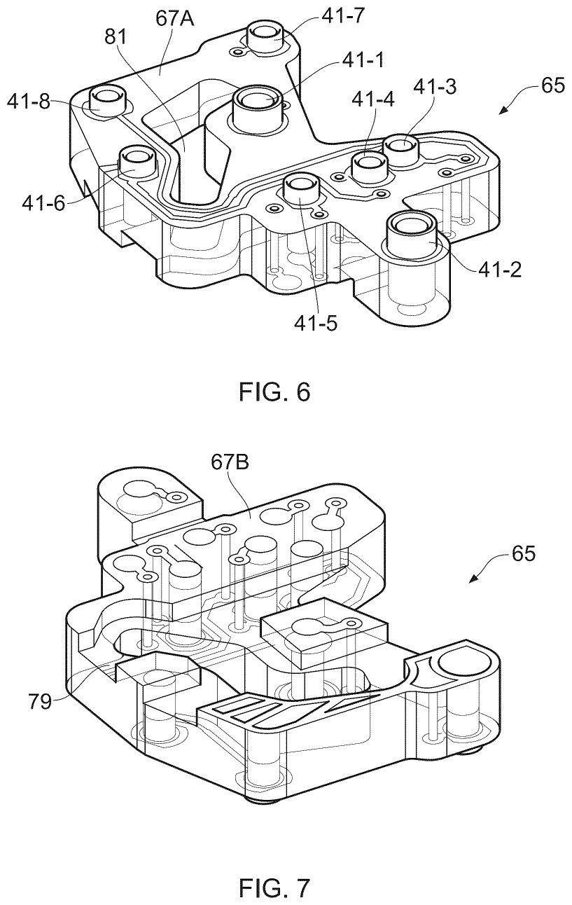

As shown in FIGS. 3 and 4, the power supply unit 31 comprises a plurality of the first electrical connectors 41-n. The first electrical connectors 41-n are mounted in the daughterboard 65. In the present embodiment, the first electrical connectors 41-n are through-hole mounted in the daughterboard 65, but other mounting techniques may be used. This mounting arrangement provides a vertical offset between the first electrical connectors 41-n and the other components in the power supply unit 31, such as the transformer 37. This separation may reduce the risk of electrical arcing between the components, for example caused by the high voltage output. A perspective view of the first surface 67A of the daughterboard 65 (separate from the motherboard 55) is shown in FIG. 6; and a perspective view of the second surface 67B of the daughterboard 65 (separate from the motherboard 55) FIG. 7.

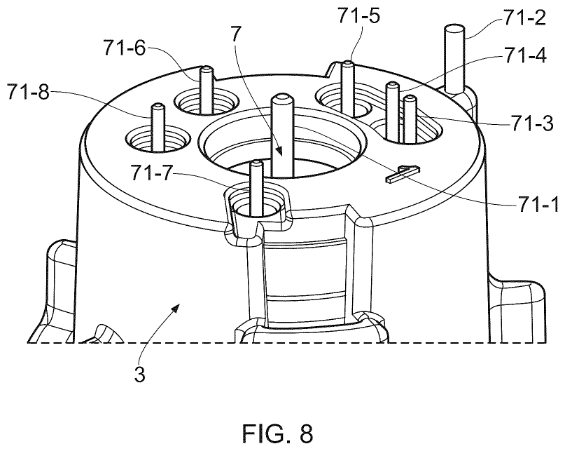

As shown in FIG. 8, the ionization vacuum pressure sensor 3 comprises a plurality of second electrical connectors 71-n. The first electrical connectors 41-n and the second electrical connectors 71-n have complementary profiles. The first electrical connectors 41-n and the second electrical connectors 71-n are aligned with each other. In the assembled vacuum pressure gauge 1, the first and second electrical connectors 41-n, 71-n cooperate with each other to establish electrical connections between the power supply unit 31 and the ionization vacuum pressure sensor 3.

In the present embodiment, the first electrical connectors 41-n each comprise an electrical socket. The electrical sockets each comprise a central longitudinal axis X-n extending substantially parallel to the central longitudinal axis X of the vacuum pressure gauge 1. The second electrical connectors 71-n each comprise an electrical pin. The electrical pins each comprise a central longitudinal axis X-n extending substantially parallel to the central longitudinal axis X of the vacuum pressure gauge 1. The vacuum pressure gauge 1 is assembled by aligning the first and second electrical connectors 41-n, 71-n and displacing the power supply unit 31 and the ionization vacuum pressure sensor 3 relative to each other in an axial direction (i.e., along the longitudinal axis X). The second electrical connectors 71-n each locate in a respective one of the first electrical connectors 41-n to establish an electrical connection. In a variant, the first electrical connectors 41-n may each comprise an electrical pin; and the second electrical connectors 71-n may each comprise an electrical socket. Other types and/or combinations of the first and second electrical connectors 41-n, 71-n may be used.

The plurality of the first electrical connectors 41-n comprise a high voltage first electrical connector 41-1 for connection to the anode 7 of the ionization vacuum pressure sensor 3. The plurality of the first electrical connectors 41-n also comprise a chassis return first electrical connector 41-2; a high voltage return first electrical connector 41-3, a first striker filament first electrical connector 41-4, a second striker filament first electrical connector 41-5; a Pirani filament A first electrical connector 41-6; a Pirani filament B first electrical connector 41-7 and a compensator first electrical connector 41-8. The plurality of the second electrical connectors 71-n comprise a high voltage second electrical connector 71-1 for connection to the high voltage first electrical connector 41-1. The plurality of the second electrical connectors 71-n also comprise a chassis return second electrical connector 71-2; a high voltage return second electrical connector 71-3, a first striker filament second electrical connector 71-4, a second striker filament second electrical connector 71-5; a Pirani filament A second electrical connector 71-6; a Pirani filament B second electrical connector 71-7 and a compensator second electrical connector 71-8. It will be understood that one or more of the first and second electrical connectors 41-n, 71-n may be omitted. The first and second electrical connectors 41-4, 41-5, 71-4, 71-5 for the striker filament may be omitted if the striker filament is omitted from the ionization vacuum pressure sensor 3. Alternatively, or in addition, one or more of the first and second electrical connectors 41-6, 41-7, 71-6, 71-7 for the Pirani filaments A and B may be omitted if the Pirani filaments A and B are omitted from the ionization vacuum pressure sensor 3.

As shown in FIG. 3, the daughterboard 65 has an outer profile which comprises a recess 77. The recess 77 is profiled to maintain a clearance between the transformer 37 and the daughterboard 65. At least one channel 79 is formed in the second surface 67B of the daughterboard 65 to form a space or a gap between the motherboard 55 and the daughterboard 65. As shown in FIG. 7, the at least one channel 79 extends at least partway around a base of the high voltage first electrical connector 41-1. The at least one channel 79 in the present embodiment is bifurcated (generally Y-shaped), but other configurations are envisaged. The daughterboard 65 also comprises at least one cut-out or aperture 81. As shown in FIG. 6, the cut-out 81 is formed between two or more of the first electrical connectors 41-n to provide improved electrical insulation. In the present embodiment, the cut-out 81 is formed between the high voltage first electrical connector 41-1 and the Pirani filament A second electrical connector 71-6; and the compensator second electrical connector 71-8.

As shown in FIG. 4, an electrical potting compound 83 is provided over the electrical components disposed on the first surface 67A of the daughterboard 65. The electrical potting compound 81 is provided to electrically insulate the components, for example to prevent arcing between the high voltage first electrical connectors 41-1 and other components or connectors. The electrical potting compound 83 may also mechanically strengthen the power supply unit 31. At least a portion of the first surface 57A of the motherboard 55 is encapsulated in the electrical potting compound 83. In the present embodiment, the electrical potting compound 83 is not applied over the second surface 57B of the motherboard 55. The electrical potting compound 83 may have a depth greater than or equal to the thickness of the daughterboard 65. In the present embodiment, the electrical potting compound 83 is applied at least partially over the first surface 67A of the daughterboard 65. The electrical potting compound 83 is not applied over the first electrical connectors 41-n. The first electrical connectors 41-n may, for example, be sealed or covered when the electrical potting compound 83 is applied. The electrical potting compound 83 is applied using a vacuum moulding process, but other techniques may be used.

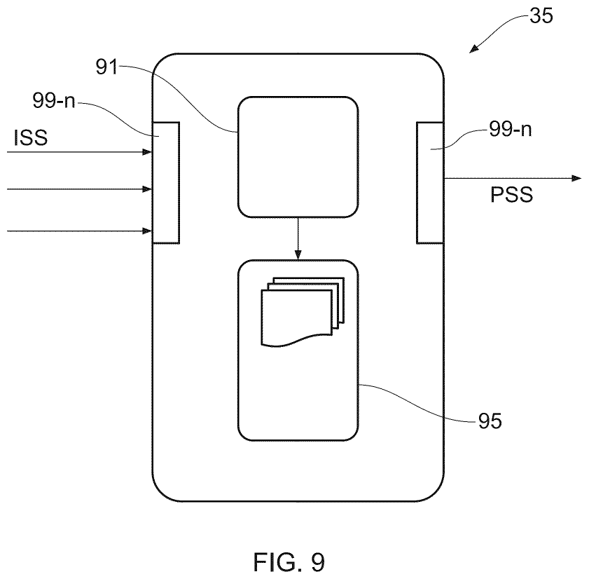

The control unit 35 is configured to control operation of the ionization vacuum pressure sensor 3. As shown in FIG. 9, the control unit 35 comprises a pressure sensor controller 91 comprising at least one electronic processor 93 and a memory (storage) device 95. A set of computational instructions is stored on the memory device 95. When executed, the computational instructions cause the at least one electronic processor 93 to control the ionization vacuum pressure sensor 3 in accordance with the method(s) described herein. The at least one processor 93 comprises at least one electrical input 97-n for receiving an input signal ISS; and at least one electrical output 99-n for outputting a control signal PSS. The input signal ISS may, for example comprise a pressure reading from the ionization vacuum pressure sensor 3. The external interface connector 17 is mounted to the control unit 35 and is supported in the end member 13 of the vacuum pressure gauge 1. The external interface connector 17 is in electrical communication with the at least one electronic processor 93 and, in use, can receive power and/or communicate with an external user interface (not shown). In this manner, the external interface connector 17 can be connected by a cable to a power source and/or external user interface or device (e.g., a computer) for communicating with the at least one electronic processor 93. In the illustrated arrangement, the interface connector 17 is a D-sub connector. Accordingly, the interface connector 17 can be connected to a power source and/or external user interface using a cable with a complimentary D-sub connector. In other embodiments, any other suitable connector can be used, e.g. an RJ45 or USB connector.

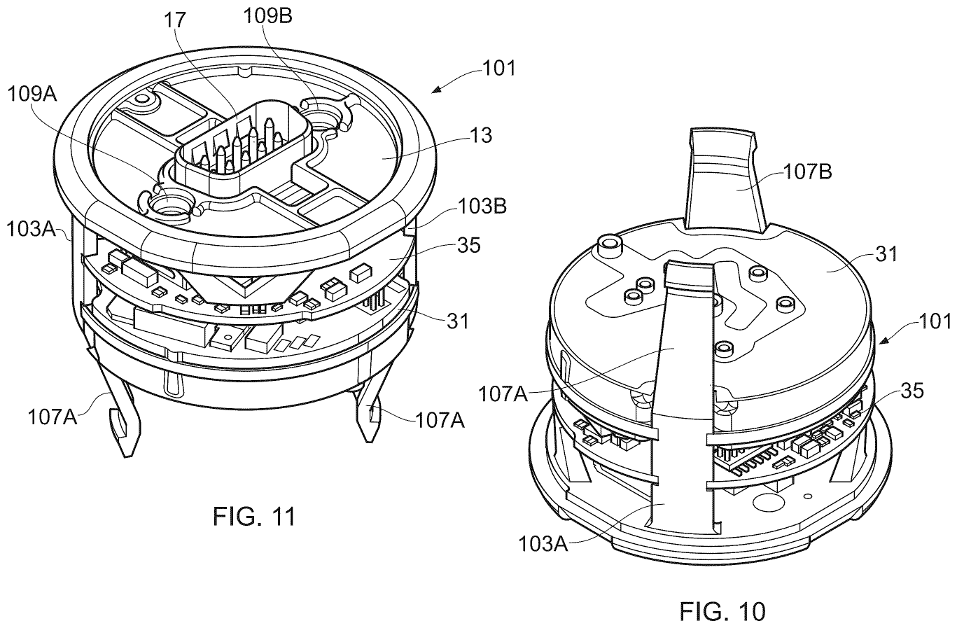

As shown in FIGS. 10 and 11, the power supply unit 31 and the control unit 35 are mounted in a chassis 101. The chassis 101 comprises a pair of diametrically opposed first and second braces 103A, 103B configured to engage the edges of the power supply unit 31 and the control unit 35. The chassis 101 may comprise a single brace, or more than two braces. The first and second braces 103A, 103B locate in respective first and second locating recesses 105A, 105B formed in an outer periphery of the power supply unit 31. The first and second braces 103A, 103B locate in the first and second locating recesses 105A, 105B to locate the power supply unit 31 axially and/or angularly. The first and second braces 103A, 103B also locate in recesses (not shown) formed in the control unit 35 to locate the control unit 35 axially and/or angularly. The chassis 101 comprises opposing first and second resilient arms 107A, 107B. The chassis 101 may comprise a single resilient arm, or more than two resilient arms. The first and second resilient arms 107A, 107B are configured releasably to engage an outer sidewall of the ionization vacuum pressure sensor 3. As shown in FIG. 11, the end member 13 is formed integrally with the chassis 101. First and second apertures 109A, 109B are formed in the end member 13 for receiving mechanical fasteners (not shown) to fasten the control unit 35 to the chassis 101. Other techniques may be employed to fasten the control unit 35 and/or the power supply unit 31 to the chassis 101. An end plate 111 can optionally be provided over the end member 13. The chassis 101 helps to reduce or prevent relative movement of the power supply unit 31 and the control unit 35, thereby reducing the mechanical load applied to the first and second control interface connectors 59-1, 59-2. In a variant, the chassis 101 could be omitted. For example, one or more mechanical fasteners may be used to fasten the control unit 35 to the power supply unit 31 without a separate chassis 101. The housing 15 may optionally be fastened to the chassis 101.

The control unit 35 is mounted to the power supply unit 31 to form a sub-assembly which can be removably mounted to the ionization vacuum pressure sensor 3. In the present embodiment, the sub-assembly includes the chassis 101, but the chassis 101 may be omitted. As shown in FIG. 10, the first electrical connectors 41-n are disposed on an underside of the sub-assembly. The power supply unit 31 is displaced axially in a first direction (towards) the ionization vacuum pressure sensor 3 to introduce each of the second electrical connectors 71-n into a respective one of the first electrical connectors 41-n. The power supply unit 31 and the control unit 35 is thereby mounted on the ionization vacuum pressure sensor 3. The power supply unit 31 is removable from the ionization vacuum pressure sensor 3. The power supply unit 31 is displaced axially in a second direction (away from) the ionization vacuum pressure sensor 3 to displace the second electrical connectors 71-n out of the respective first electrical connectors 41-n. In the present embodiment, the power supply unit 31 and the control unit 35 are removed as a single unit with the chassis 101 and the housing 15. The housing 15 is secured in place to limit or prevent access to the power supply unit 31.

As outlined above, the ionization vacuum pressure sensor 3 is fastened to the base 9 which, in use, is fastened to the vacuum system component VSC. At least in certain embodiments, the power supply unit 31 may be removed leaving the ionization vacuum pressure sensor 3 and the base 9 in situ on the vacuum system component VSC.

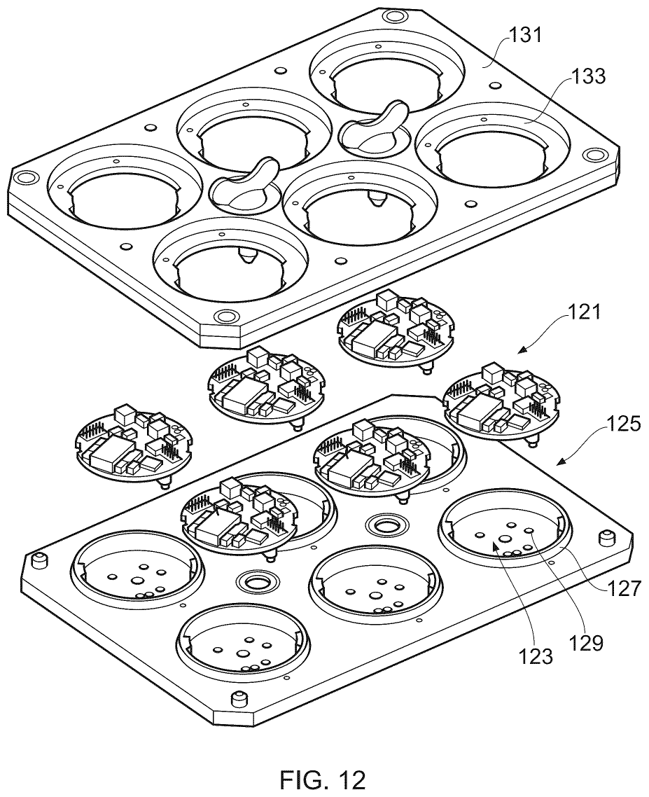

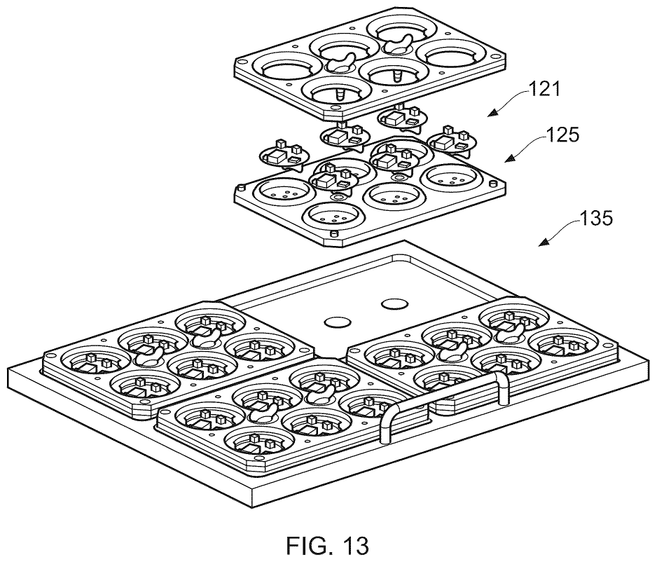

The application of the electrical potting compound 83 to the power supply unit 31 will now be described with reference to FIGS. 12 and 13. It is envisaged that the process will be performed simultaneously for a plurality of the power supply units 31. However, for the sake of brevity, the process is described herein with reference to a single power supply unit 31.

The electrical components (including the transformer 37) of the power supply unit 31 and the daughterboard 65 are surface mounted to the motherboard 55 to form a sub-assembly 121. The electrical potting compound 83 is applied to the sub-assembly 121. In particular, the sub-assembly 121 is supported in a mould tool 125 defining a mould cavity 123. In the present embodiment, the mould tool 125 comprises an annular wall 127 which forms a sidewall of the mould cavity 123. The mould tool 125 in the present embodiment is configured to close or cover each of the first electrical connectors 41-n in order to prevent the electrical potting compound 83 contaminating the contact surface. In the present embodiment, the mould tool 125 comprise a plurality of mould recesses 129 configured to receive the ends of first electrical connectors 41-n. The first electrical connectors 41-n locate in the mould recesses 129, thereby allowing the first surface 67A of the daughterboard 65 to contact a base of the mould cavity 123 in a face-to-face arrangement. A distal end of the first electrical connectors 41-n may be seated against a base of the mould cavity 123 or the mould recesses 129, preferably sealing each of the first electrical connectors 41-n. Alternatively, or in addition, the mould cavity 123 may comprise one or more projections (not shown) for locating in the first electrical connectors 41-n. A release agent may be provided in the mould cavity 123 to facilitate removal of the power supply unit 31 after the electrical potting compound 83 has cured.

The sub-assembly 121 is positioned in the mould tool 125 such that an outer portion of the first surface 57A of the motherboard 55 is seated on the annular wall 127. The motherboard 55 at least substantially seals the mould cavity 123. The first surface 57A of the motherboard 55 faces into the mould cavity 123. A closure member 131 is mounted to the mould tool 125 to secure the sub-assembly 121 in position. The closure member 131 comprises an annular projection 133 for engaging the second surface 57B of the motherboard 55. A seal is formed between the motherboard 55 and the mould tool 125 and/or the closure member 131 at least substantially to seal the mould cavity 123. The seal may be formed between an outer edge of the motherboard 55 and a sidewall of the mould cavity 123. Alternatively, or in addition, the seal may be formed between the second surface 57B of the motherboard 55 and the annular projection 133 of the closure member 131.

The electrical potting compound 83 is injected into the mould cavity 123 at least partially to encapsulate the daughterboard 65. The electrical potting compound 83 is provided around a perimeter of the daughterboard 65. The depth of the electrical potting compound 83 (from the first surface 57A of the motherboard 55) may be less than the thickness of the daughterboard 65. Preferably, however, the depth of the electrical potting compound 83 is substantially equal to or greater than the thickness of the daughterboard 65. The electrical potting compound 83 may be form a thin layer over the first surface 67A of the daughterboard 65. The electrical potting compound 83 fills the mould cavity 123 and encapsulates the electrical components provided on the first surface 57A of the motherboard 55. The electrical potting compound 83 is introduced under vacuum in the present embodiment to enhance penetration. The mould recesses 129 formed in the mould tool 125 prevent the electrical potting compound 83 entering the first electrical connectors 41-n.

The electrical potting compound 83 is cured in the mould cavity 123. The closure member 131 is removed and the power supply unit 31 is removed. The power supply unit 31 is then installed in the vacuum pressure gauge 1.

As shown in FIG. 12, the mould tool 125 comprises a plurality of the mould cavities 123. In use, a plurality of the sub-assemblies 121 are installed in the mould tool 125 and the electrical potting compound 83 introduced simultaneously into the mould cavities 123. As shown in FIG. 13, a plurality of the mould tools 125 may be processed simultaneously. A jig 135 is provided for supporting a plurality of the mould tools 125.

It will be appreciated that various changes and modifications can be made to the present invention without departing from the scope of the present application. The power supply unit 31 and the control unit 35 in the present embodiment have been described as being provided on separate printed circuit boards (PCBs). In a variant, the power supply unit 31 and the control unit 35 could be provided on the same printed circuit board (PCB).

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A power supply unit configured to be integrated into a vacuum pressure gauge comprising a vacuum pressure sensor, the power supply unit comprising:
a motherboard comprising a first surface and a second surface, wherein a transformer having a primary coil and a secondary coil is mounted to the motherboard; and
a daughterboard comprising one or more first electrical connectors n)-for supplying power to the vacuum pressure sensor;
wherein at least a portion of the first surface of the motherboard and at least a portion of the daughterboard are encapsulated in an electrical potting compound; and the second surface of the motherboard is at least substantially free of the electrical potting compound.

2. The power supply unit as claimed in claim 1, wherein the daughterboard is mounted to the first surface of the motherboard, the one or more first electrical connectors on the daughterboard being spaced apart from the first surface of the motherboard.

3. The power supply unit as claimed in claim 1, wherein the first electrical connectors are unimpeded by the electrical potting compound.

4. The power supply unit as claimed in claim 1, wherein the electrical potting compound is provided at least partway around an outer circumference of the daughterboard.

5. The power supply unit as claimed in claim 1, wherein the transformer has a first major surface oriented in the same direction as the first surface of the motherboard, wherein the first major surface of the transformer is at least partially encapsulated in the electrical potting compound.

6. The vacuum pressure gauge comprising a power supply unit as claimed in claim 1.

7. A method of assembling a power supply unit configured to be integrated into a vacuum pressure gauge, the power supply unit comprising a motherboard comprising a first surface and a second surface, wherein a transformer having a primary coil and a secondary coil is mounted to the motherboard; and a daughterboard comprising one or more first electrical connectors; the method comprising:
mounting the daughterboard to the first surface of the motherboard to form a sub-assembly;
locating the sub-assembly in a mould cavity and forming a seal around a periphery of the motherboard, and at least substantially sealing the mould cavity;
introducing an electrical potting compound into the mould cavity at least partially to encapsulate the daughterboard and the first surface of the motherboard, wherein the seal formed around the periphery of the motherboard at least substantially prevents the electrical potting compound from encapsulating the second side of the motherboard; and
curing the electrical potting compound and then removing the power supply unit from the mould cavity.

8. The method as claimed in claim 7, wherein the seal is formed between the motherboard and an internal wall of the mould cavity.

9. The method as claimed in claim 7 comprising forming a seal around the one or more first electrical connectors to prevent the electrical potting compound encapsulating the one or more first electrical connectors.

10. The method as claimed in claim 9, wherein the or each first electrical connector is at least partially located in a mould recess formed in the mould cavity, the seal being formed between an internal wall of the mould recess and an outer wall of the first electrical connector.
